(19) United States
(12) Patent Application Publication
(10) Pub. No.: US 2012/0169366 A1
(43) Pub. Date: Jul. 5, 2012

(54) SOCKET CONTACT FOR TESTING A SEMICONDUCTOR

(76) Inventors: HYUN-GUEN IY, Asan-si (KR); Sang-Jin Kyung, Cheonan-si (KR); Won-Jin Kong, Asan-si (KR)

(21) Appl. No.: 13/288,524

(22) Filed: Nov. 3, 2011

(30) Foreign Application Priority Data
Jan. 4, 2011 (KR) 10-2011-0000632

(51) Int. Cl. G01R 1/067

(52) U.S. Cl. 324/755.01

(57) ABSTRACT

A socket contact for testing a semiconductor. The socket contact includes a first contact portion, a second contact portion, and first and second body portions connecting the first contact portion and the second contact portion, wherein each of the first and second body portions has a first end, a second end opposite to the first end, and a connecting portion between the first and second ends, the first end of the first body portion and the first end of the second body portion contact the first contact portion, the second end of the first body portion and the second end of the second body portion contact the second contact portion, and the connecting portion of the first body portion and the connecting portion of the second body portion are spaced apart from each other.

### CROSS-REFERENCE TO RELATED APPLICATION

This application claims priority from Korean Patent Application No. 10-2011-0000632 filed on Jan. 4, 2011 in the Korean Intellectual Property Office, and all the benefits accruing therefrom under 35 U.S.C.119, the contents of which are herein incorporated by reference in their entirety.

### BACKGROUND

1. Technical Field

The present inventive concept relates to a socket contact for testing a semiconductor.

2. Discussion of the Related Art

Wafer fabrication and packaging are completed to form a semiconductor chip, and a plurality of semiconductor chips are assembled to be electrically connected to each other on a printed circuit board (PCB). The plurality of semiconductor chips assembled on a PCB are tested by various testing methods and are sorted into acceptable or unacceptable products. Throughout the testing procedures, product reliability is tested. For example, one representative reliability test using a socket is a burn-in test. In order to determine whether a semiconductor device is defective, the burn-in test applies a high temperature and/or a high voltage, that are beyond the normal levels, to a semiconductor device to detect and eliminate latent defects which might appear at an early stage of regular use of the semiconductor device. Since 32 to 256 sockets are incorporated into a single interface board, many semiconductors can be simultaneously tested by the burn-in test.

A socket contact, such as, for example, a land grid array (LGA) socket for testing a semiconductor has been formed in a bow shape. However, it is difficult to use automation to insert the bow shaped socket contact into a housing.

### SUMMARY

The embodiments of the present inventive concept provide a socket contact for testing a semiconductor, which allows for automation and is suitable for miniaturization, and has an extended cycle life by reducing stress applied thereto.

The above and other objects of the embodiments of the present inventive concept will be described in or be apparent from the following description of exemplary embodiments.

According to an embodiment of the present inventive concept, there is provided a socket contact including a first contact portion, a second contact portion, and first and second body portions connecting the first contact portion and the second contact portion, wherein each of the first and second body portions has a first end, a second end opposite to the first end, and a connecting portion between the first and second ends, the first end of the first body portion and the first end of the second body portion contact the first contact portion, the second end of the first body portion and the second end of the second body portion contact the second contact portion, and the connecting portion of the first body portion and the connecting portion of the second body portion are spaced apart from each other.

According to an embodiment of the inventive concept, a socket contact comprises a first contact portion positioned at a first end of the socket contact, a second contact portion positioned at a second end of the socket contact, and a first connecting portion and a second connecting portion connected between the first and second contact portions, wherein the first connecting portion is in a different plane from the second connecting portion, and the first and second connecting portions protrude in different directions with respect to an imaginary line connecting the first and second contact portions.

The first and second connecting portions may each comprise at least two legs making an oblique angle with respect to each other, and with respect to the imaginary line connecting the first and second contact portions. The plane of the first connecting portion may be parallel to the plane of the second connecting portion. When the socket contact is positioned in a housing for testing a semiconductor, the second connecting portion may overlap and be in a different plane from a first connecting portion of an adjacent socket contact positioned in the housing. A fixing portion may protrude from the first contact portion or the second contact portion for fixing the socket contact in a housing for testing a semiconductor.

### BRIEF DESCRIPTION OF THE DRAWINGS

The above and other features of the embodiments of the present inventive concept will become more apparent by describing in detail exemplary embodiments thereof with reference to the attached drawings in which:

FIG. 1 is a perspective view of a socket contact for testing a semiconductor according to an embodiment of the present inventive concept;

FIG. 2 is a side perspective view illustrating an arrangement of a plurality of socket contacts for testing a semiconductor according to an embodiment of the present inventive concept;

FIG. 3 is a perspective view of a socket contact for testing a semiconductor according to another embodiment of the present inventive concept;

FIG. 4 is an exploded perspective view illustrating an assembly of a plurality of socket contacts for testing semiconductors according to an embodiment of the present inventive concept;

FIG. 5 is a perspective view illustrating a state in which socket contacts for testing semiconductors according to an embodiment of the present inventive concept are assembled in a housing and a body; and

FIGS. 6 to 9 are perspective views illustrating assembly of socket contacts for testing semiconductors according to an embodiment of the present inventive concept.

### DETAILED DESCRIPTION OF THE EMBODIMENTS

Embodiments of the present inventive concept and methods of accomplishing the same may be understood more readily by reference to the following detailed description of exemplary embodiments and the accompanying drawings. The present inventive concept may, however, be embodied in many different forms and should not be construed as being limited to the embodiments set forth herein. In the drawings, the thickness of layers and regions may be exaggerated for clarity.

Like numbers may refer to like elements throughout. As used herein, the term “and/or” includes any and all combinations of one or more of the associated listed items.

Socket contacts for testing a semiconductor according to embodiments of the present inventive concept are described below with reference to the drawings.

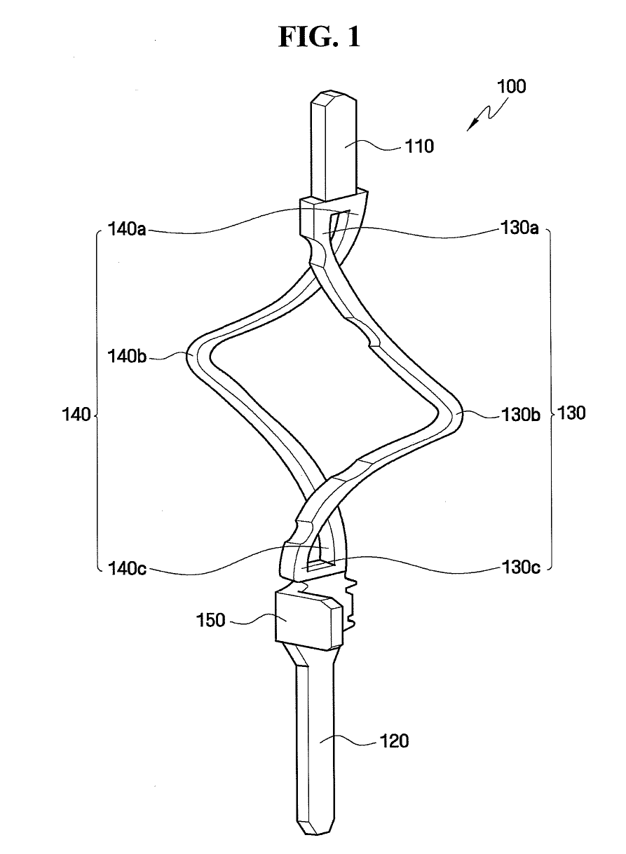

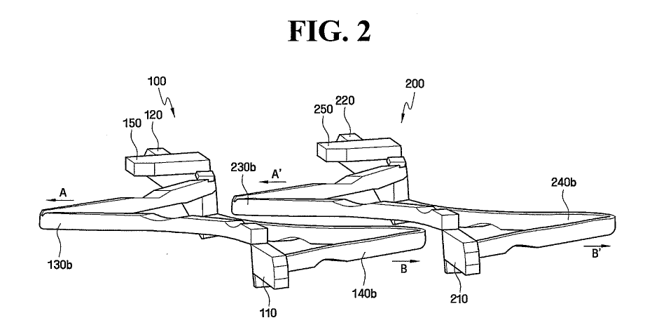

A socket contact for testing a semiconductor according to an embodiment of the present inventive concept is described with reference to FIGS. 1 and 2. FIG. 1 is a perspective view of a socket contact for testing a semiconductor according to an embodiment of the present inventive concept, and FIG. 2 is a side perspective view illustrating an arrangement of a plurality of socket contacts for testing a semiconductor according to an embodiment of the present inventive concept.

Referring to FIG. 1, a socket contact 100 for testing a semiconductor according to the embodiment of the present inventive concept includes a first contact portion 110, a second contact portion 120, a first body portion 130, and a second body portion 140.

More specifically, as shown in FIG. 1, the socket contact 100 includes a first contact portion 110, a second contact portion 120, and first and second body portions 130 and 140 connecting the first contact portion 110 and the second contact portion 120.

As shown in FIG. 1, the first body portion 130 extends from the first contact portion 110 to the second contact portion 120 to be connected between the first and second contact portions 110 and 120. Likewise, the second body portion 140 extends from the first contact portion 110 to the second contact portion 120 to be connected between the first and second contact portions 110 and 120.

The first body portion 130 and the second body portion 140 have first ends 130a and 140a, connecting portions 130b and 140b, and second ends 130c and 140c, respectively. The first end 130a of the first body portion 130 contacts the first contact portion 110, the second end 130c of the first body portion 130 contacts the second contact portion 120, and the first and second ends 130a and 130c of the first body portion 130 are connected to each other by the connecting portion 130b. Likewise, the first end 140a of the second body portion 140 contacts the first contact portion 110, the second end 140c of the second body portion 140 contacts the second contact portion 120, and the first and second ends 140a and 140c of the second body portion 140 are connected to each other by the connecting portion 140b.

In other words, the first end 130a of the first body portion 130 and the first end 140a of the second body portion 140 contact the first contact portion 110, and the second end 130c of the first body portion 130 and the second end 140c of the second body portion 140 contact the second contact portion 120. The first ends 130a and 140a of the first and second body portions 130 and 140 are connected to the second ends 130c and 140c by the connecting portions 130b and 140b, respectively.

The connecting portion 130b of the first body portion 130 and the connecting portion 140b of the second body portion 140 are spaced apart from each other. As shown, the first end 130a of the first body portion 130 and the first end 140a of the second body portion 140 are connected to each other by the first contact portion 110, and the second end 130c of the first body portion 130 and the second end 140c of the second body portion 140 are connected to each other by the second contact portion 120. The connecting portion 130b of the first body portion 130 and the connecting portion 140b of the second body portion 140 are separated from each other.

More specifically, when a first plane including the first contact portion 110 and the second contact portion 120 is defined, the connecting portion 130b of the first body portion 130 protrudes from the first plane in a first direction and the connecting portion 140b of the second body portion 140 protrudes from the first plane in a second direction. According to an embodiment, the first direction and the second direction are different from each other. For example, the first direction and the second direction are opposite to each other.

When the connecting portion 130b of the first body portion 130 and the connecting portion 140b of the second body portion 140 protrude in different directions, two spaces are defined with respect to the plane including the first contact portion 110 and the second contact portion 120. The connecting portion 130b of the first body portion 130 protrudes to one of the two spaces and the connecting portion 140b of the second body portion 140 protrudes to the other of the two spaces.

The first end 130a of the first body portion 130 and the first end 140a of the second body portion 140 are connected to each other at the first contact portion 110, and the second end 130c of the first body portion 130 and the second end 140c of the second body portion 140 are connected to each other at the second contact portion 120. Since the connecting portion 130b of the first body portion 130 and the connecting portion 140b of the second body portion 140 protrude in different directions, the first body portion 130 and the second body portion 140 form, for example, an arcuate shape. As shown in FIG. 1, opposite ends of each of the first and second body portions 130 and 140 contact each other and the mid portions connecting the opposite ends extend in opposite directions.

In the illustrated embodiment, the connecting portion 130b of the first body portion 130 and the connecting portion 140b of the second body portion 140 are shaped to protrude at their mid portions, centered between the first and second contact portions 110, 120. Alternatively, the connecting portion 130b of the first body portion 130 and the connecting portion 140b of the second body portion 140 may be biased to one side of the first body portion 130 and the second body portion 140. For example, according to an embodiment, protruding parts of the respective connecting portions 130b and 140b may be formed to be closer to the second contact portion 120 than to the first contact portion 110, or vice versa.

In addition, in the illustrated embodiment, the protruding parts of the respective connecting portions 130b and 140b of the first and second body portions 130 and 140 are formed to be symmetrical with each other. In other embodiments, the protruding part of the connecting portion 130b may be formed to be closer to the first contact portion 110 than the protruding part of the connecting portion 140b. Alternatively, the protruding part of the connecting portion 140b may be formed to be closer to the first contact portion 110 than the protruding part of the connecting portion 130b.

Likewise, the protruding part of the connecting portion 130b may be formed to be closer to the second contact portion 120 than the protruding part of the connecting portion 140b. Alternatively, the protruding part of the connecting portion 140b may be formed to be closer to the second contact portion 120 than the protruding part of the connecting portion 130b.

The connecting portion 130b of the first body portion 130 and the connecting portion 140b of the second body portion 140 have elasticity to absorb pressure applied to the first and second contact portions 110, 120. In some embodiments, elastic characteristics can be increased by configuring the first body portion 130 and the second body portion 140 in a wave form shape.

According to an embodiment, a plane contacting the first contact portion 110 is not coplanar with a plane contacting the second contact portion 120. In other words, a plane in which a part of the connecting portion 130b contacting the second contact portion 120 lies is different from the plane in which the other part of the connecting portion 130b contacting the first contact portion 110 lies, so that upper and lower parts of the connecting portion 130b are in different planes from each other.

Likewise, a plane in which a part of the connecting portion 140b contacting the second contact portion 120 lies is different from the plane in which the other part of the connecting portion 140b contacting the first contact portion 110 lies, so that upper and lower parts of the connecting portion 140b are in different planes from each other.

According to another embodiment, extending from the first contact portion 110 to the second contact portion 120, the connecting portion 130b of the first body portion 130 and the connecting portion 140b of the second body portion 140 are twisted.

The first body portion 130 and the second body portion 140 configured in a wave shape may be twisted, which increases the inward stability of the first contact portion 110 and the second contact portion 120.

Elasticity, which can be increased by employing the wave-form or twisted configurations of the connecting portions 130b and 140b, allows the socket contact to have stability with respect to a pressure applied from the first contact portion 110 and a pressure applied from the second contact portion 120 to the first and second body portions 130 and 140. In addition, since the socket contact is stable against applied stress, the life of the socket contact is extended.

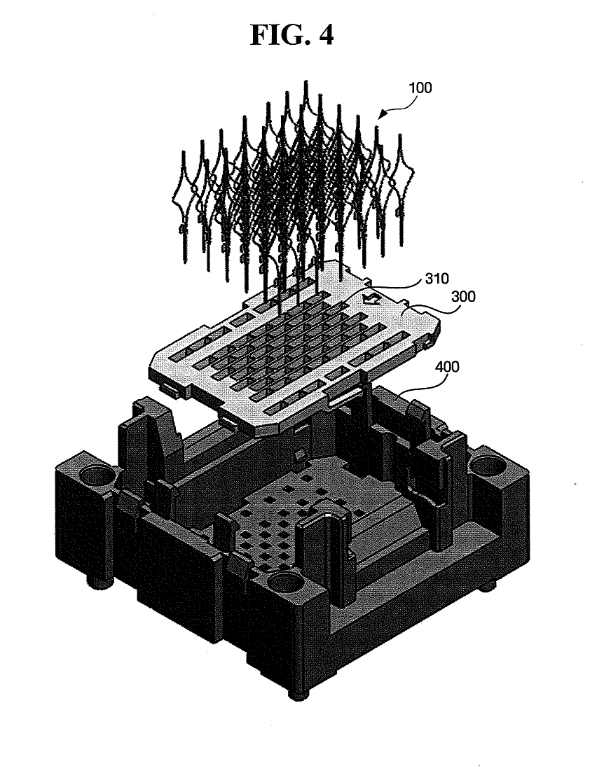

According to an embodiment, a fixing portion 150 protruding from the first contact portion 110 or the second contact portion 120 is further provided to fix the socket contact for testing a semiconductor in a housing. A fixing mechanism of the fixing portion 150 is described below with reference to FIGS. 4 to 9.

Referring to FIG. 2, with regard to a socket contact 100 for testing a semiconductor, a plane including the connecting portion 130b of a first body portion and a plane including the connecting portion 140b of a second body portion are different from each other. The planes including the connecting portions 130b and 140b are parallel to each other. In addition, as shown in FIG. 2, with regard to another socket contact 200 for testing a semiconductor, the planes including connecting portions 230b and 240b of the socket contact 200 are the same as the planes including the connecting portions 130b and 140b, respectively.

The socket contact 100 and the socket contact 200 include connecting portions 130b and 230b of first body portions and connecting portions 140b and 240b of second body portions, respectively. As shown in FIG. 2, the connecting portion 130b of the first body portion protrudes from a plane or a line including the first contact portion 110 and the second contact portion 120 in a direction indicated by reference symbol ‘A’ and the connecting portion 140b of the second body portion protrudes in a direction indicated by reference symbol ‘B.’ As shown, the plane including the connecting portion 130b protruding in the A direction is different from the plane including the connecting portion 140b protruding in the B direction, and the two planes are parallel to each other.

Likewise, in the socket contact 200, the connecting portion 230b of the first body portion protrude from a plane or a line including the first contact portion 210 and the second contact portion 220 in the A direction and the connecting portion 240b of the second body portion protrudes in the B direction. As shown, the plane including the connecting portion 230b protruding in the A direction is different from the plane including the connecting portion 240b protruding in the B direction, and the two planes are parallel to each other.

According to an embodiment, with regard to the socket contacts 100 and 200 for testing two adjacent semiconductors, a distance between the plane including the connecting portion 130b and the plane including the connecting portion 140b is the same as a distance between the plane including the connection portion 230b and the plane including the connecting portion 240b.

The distance between two planes refers to the shortest distance between the plane including the connecting portions 130b and 230b of the respective first body portions and the plane including the connecting portions 140b and 240b of the respective second body portions.

The connecting portions 130b and 230b of the first body portions protrude in the A direction and an A′ direction, which are the same or substantially the same directions, and the connecting portions 140b and 240b of the second body portion protrude in the B direction and the B′ direction, which are the same or substantially the same directions.

As described above, a distance between the plane including the connecting portion 130b and the plane including the connecting portion 140b is equal to the distance between the plane including the connecting portions 230b and the plane including the connecting portion 240b, and the connecting portions 130b and 230b of the first body portions and the connecting portions 140b and 240b of the second body portion protrude in the same directions, respectively. Therefore, when the socket contacts 100, 200 are arranged next to each other, the connecting portion 140b of the second body portion of the socket contact 100 overlaps the connecting portion 230b of the first body portion of the socket contact 200.

As described above, the respective socket contacts are formed such that their connecting portions are positioned on different planes and connecting portions of two adjacent socket contacts overlap each other, thereby reducing a distance between the respective socket contacts. Accordingly, a unit pitch between the respective socket contacts is suitable for miniaturization and compaction. In addition, while only two socket contacts are shown in the illustrated embodiment, multiple socket contacts for testing other semiconductors can be continuously arranged.

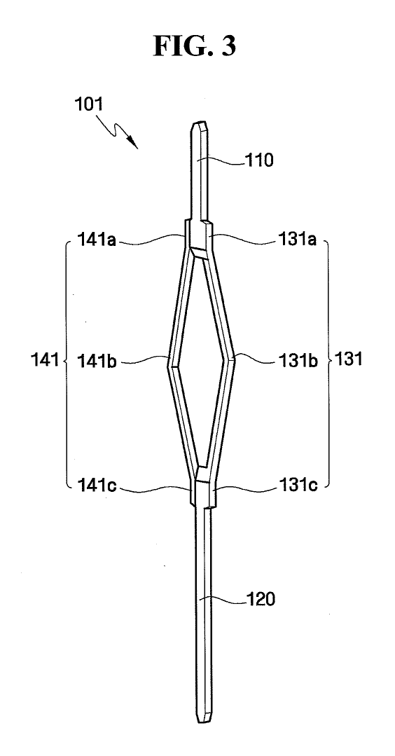

A socket contact for testing a semiconductor according to another embodiment of the present inventive concept is described with reference to FIG. 3. FIG. 3 is a perspective view of a socket contact for testing a semiconductor according to another embodiment of the present inventive concept.

The socket contact 101 according to the embodiment of the present inventive concept is different from the socket contact 100 in that a connecting portion 131b of a first body portion 131 and a connecting portion 141b of a second body portion 141 are coplanar. For convenience of explanation, the description of the embodiment of the inventive concept in connection with FIG. 3focuses on the differences from the embodiments described in connection with FIGS. 1 and 2.

As shown in FIG. 3, the illustrated socket contact 101 includes a first contact portion 110, a second contact portion 120, a first body portion 131 and a second body portion 141.

The first body portion 131 and the second body portion 141 include first ends 131a and 141a, second ends 131c and 141c, and connecting portions 131b and 141b connecting the first and second ends 131a and 131c, and 141a and 141c, respectively. In addition, the first end 131a of the first body portion 131 and the first end 141a of the second body portion 141 contact the first contact portion 110, and the second end 131c of the first body portion 131 and the second end 141c of the second body portion 141 contact the second contact portion 120. The connecting portion 131b of the first body portion 131 and the connecting portion 141b of the second body portion 141 are spaced apart from each other.

If a first plane including the first contact portion 110 and the second contact portion 120 is defined, the connecting portion 131b of the first body portion 131 and the connecting portion 141b of the second body portion 141 are positioned in the first plane. In other words, the connecting portion 131b of the first body portion 131 and the connecting portion 141b of the second body portion 141 are coplanar.

As shown in FIG. 3, the first end 131a, connecting portion 131b and second end 131c of the first body portion 131 and the first end 141a, connecting portion 141b and second end 141c of the second body portion 141, form a diamond shape, wherein the first body portion 131 and the second body portion 141 are coplanar. The connecting portion 131b of the first body portion 131 protrudes and extends from the first contact portion 110 in a first direction, and the connecting portion 141b of the second body portion 141 protrudes and extends from the first contact portion 110 in a second direction different from the first direction.

The connecting portion 131b of the first body portion 131 and the connecting portion 141b of the second body portion 141 protrude from the first contact portion 110 in different directions and the respective connecting portions 131b and 141b are coplanar and are also combined with the second contact portion 120. Accordingly, the first body portion 131 and the second body portion 141 are formed in a diamond shape. According to another embodiment, the combination of the first and second body portions may form an oval or “eye” shape.

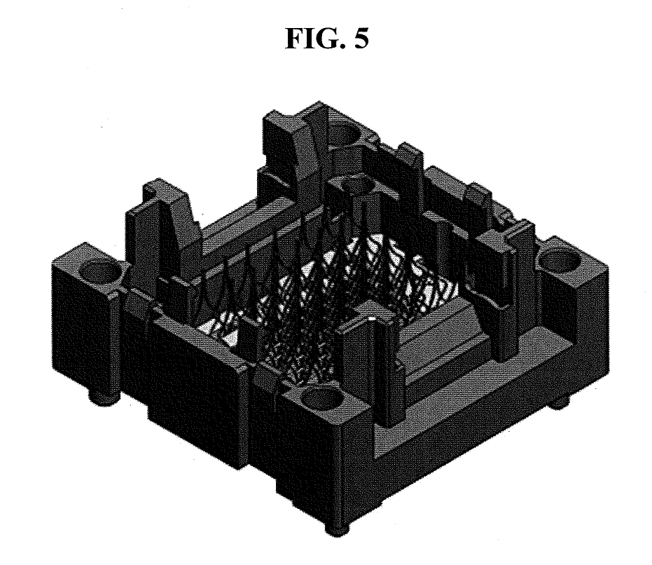

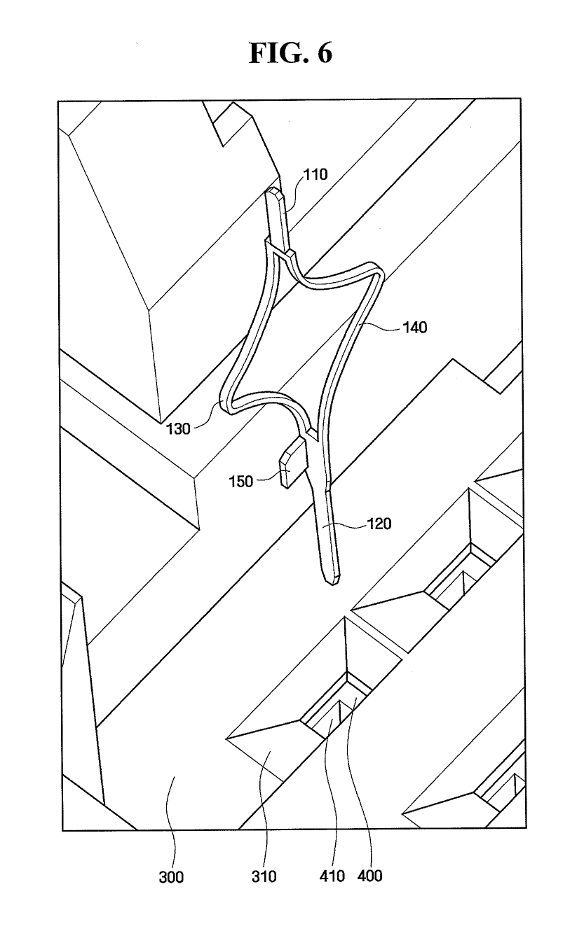

An assembly in which socket contacts for testing semiconductors are arranged in a housing is described with reference to FIGS. 4 to 9. FIG. 4 is an exploded perspective view illustrating an assembly of socket contacts for testing semiconductors according to an embodiment of the present inventive concept, FIG. 5 is a perspective view illustrating an assembled state in which socket contacts for testing semiconductors according to an embodiment of the present inventive concept are assembled with a housing and a body, and FIGS. 6 to 9 are perspective views illustrating assembly of socket contacts for testing semiconductors according to an embodiment of the present inventive concept.

Referring to FIGS. 4 and 5, a plurality of socket contacts 100 for testing semiconductors are arranged while penetrating a housing 300 and a body 400. More specifically, the housing 300 includes a plurality of insertion holes 310, and the body 400 also includes a plurality of insertion holes 410. A second contact portion 120 of each of the socket contacts 100 penetrates the insertion hole 310 of the housing 300 and the insertion hole 410 of the body 400, so that a portion of the second contact portion 120 is exposed at a rear surface of the body 400. The second contact portion 120 is exposed at the rear surface of the body 400 in such a manner to be electrically connected to, for example, a circuit board. The first contact portion 110 may be electrically connected to, for example, an integrated circuit.

The housing 300 is mounted inside the body 400, and each of the plurality of insertion holes 310 of the housing 300 are arranged to correspond to each of the plurality of insertion holes 410 of the body 400. According to an embodiment, arrangement of the plurality of socket contacts 100 is determined according to the arrangement of the plurality of insertion holes 310 and 410 of the housing 300 and the body 400. For example, the pitch and arrangement method of the socket contacts 100 is determined by the pitch and arrangement method of the plurality of insertion holes 310 and 410 of the housing 300 and the body 400.

As shown in FIG. 6, the housing 300 is disposed in the body 400 such that the insertion holes 310 of the housing 300 overlap the insertion holes 410 of the body 400. Accordingly, the second contact portion 120 of the socket contact 100 is able to be inserted into the insertion holes 310 and 410. However, the shapes of the housing 300 and the body 400 and the arrangement of the insertion holes 310 and 410 is not limited to what is shown, and may vary.

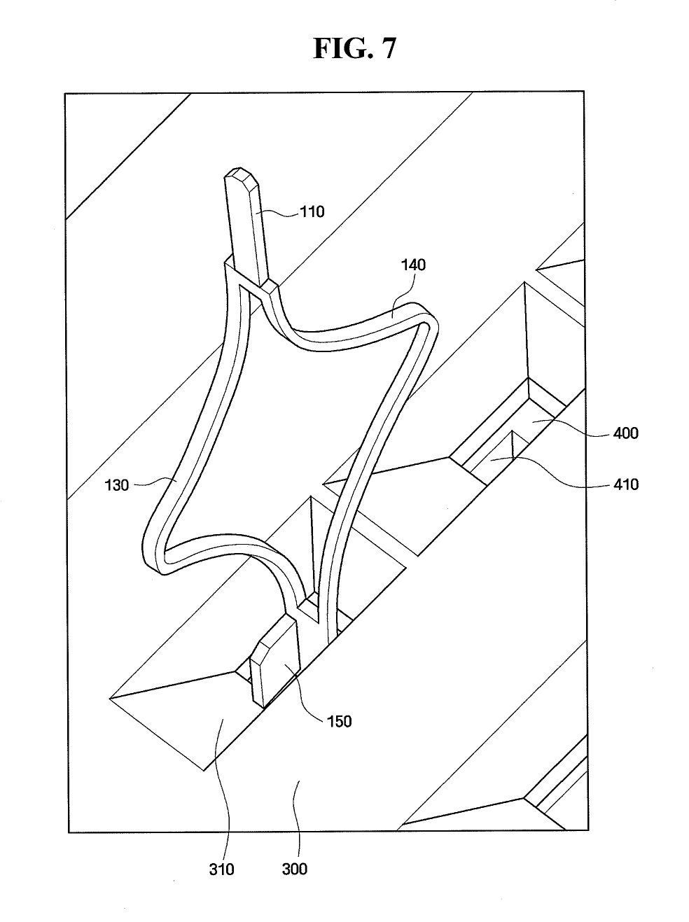

As shown in FIG. 7, the socket contact 100 is fixed by a fixing portion 150 protruding from the second contact portion 120. More specifically, a width of the insertion hole 410 of the body 400 is smaller than a width of the insertion hole 310 of the housing 300. For example, the second contact portion 120 is inserted into the insertion hole 410 of the body 400 while, due to the smaller width of the insertion hole 410 than a width of the insertion hole 310, the fixing portion 150 is not inserted into the insertion hole 410 of the body 400. In addition, the insertion hole 310 of the housing 300 has a width enough to allow the second contact portion 120 and the fixing portion 150 to be inserted therein.

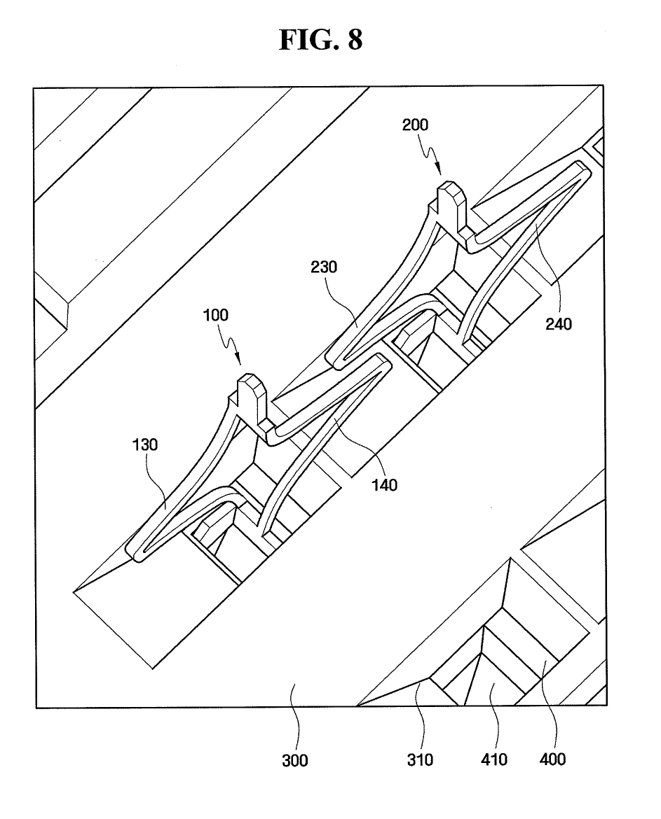

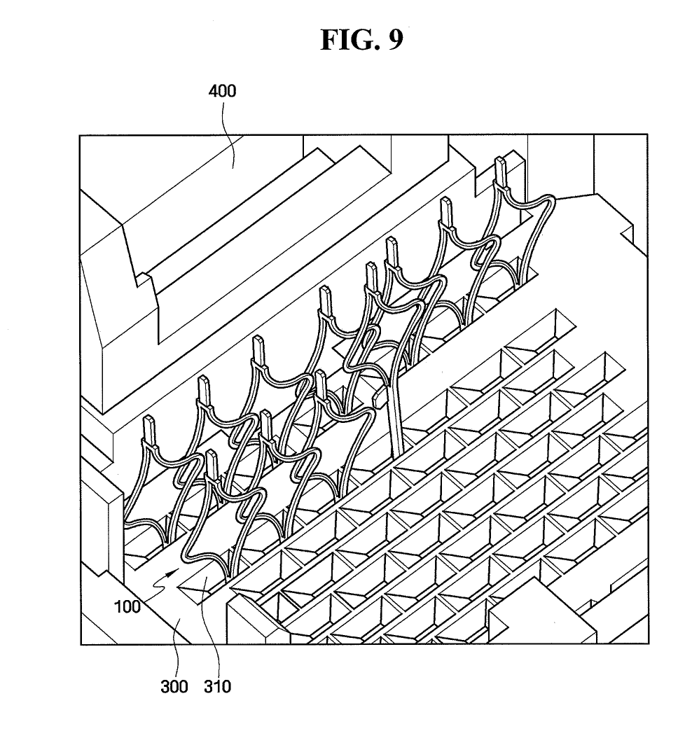

Next, as shown in FIGS. 8 and 9, the plurality of socket contacts 100 and 200 are inserted into adjacent insertion holes 310 and 410. As described above, the first body portion 130 and the second body portion 140 of a socket contact 100 protrude in different directions. Likewise, the first body portion 230 and the second body portion 240 of another socket contact 200 also protrude in different directions. Further, the second body portions 140 of first contact 100 overlaps the overlaps the first body portion 230 of the adjacent second contact 200. Accordingly, an array of overlapping adjacent contacts may be formed, thereby maximizing available space. Therefore, the embodiments of the inventive concept can be applied to an array of socket contacts with a small pitch, thereby improving the manufacturability.

While the present inventive concept has been particularly shown and described with reference to exemplary embodiments thereof, it will be understood by those of ordinary skill in the art that various changes in form and details may be made therein without departing from the spirit and scope of the present inventive concept as defined by the following claims.

What is claimed is:

1. A socket contact comprising:
a first contact portion;
a second contact portion; and
first and second body portions connecting the first contact portion and the second contact portion to each other,
wherein each of the first and second body portions has a first end, a second end opposite to the first end, and a connecting portion between the first and second ends, the first end of the first body portion and the first end of the second body portion contact the first contact portion, the second end of the first body portion and the second end of the second body portion contact the second contact portion, and the connecting portion of the first body portion and the connecting portion of the second body portion are spaced apart from each other.

2. The socket contact of claim 1, wherein the connecting portion of the first body portion protrudes in a first direction from a plane including the first and second contact portions, and the connecting portion of the second body portion protrudes from the plane in a second direction, and the first direction and the second direction are different from each other.

3. The socket contact of claim 2, wherein the first direction and the second direction are opposite with respect to each other.

4. The socket contact of claim 2, wherein the connecting portion of the first body portion and the connecting portion of the second body portion have elasticity.

5. The socket contact of claim 2, wherein, when the socket contact is positioned in a housing for testing a semiconductor, the connecting portion of the second body portion overlaps a connecting portion of a first body portion of an adjacent socket contact positioned in the housing.

6. The socket contact of claim 1, wherein the connecting portion of the first body portion and the connecting portion of the second body portion are coplanar.

7. The socket contact of claim 6, wherein a combination of the first body portion and the second body portion form a diamond shape.

8. The socket contact of claim 1, wherein the connecting portion of the first body portion and the connecting portion of the second body portion are twisted.

9. The socket contact of claim 8, wherein the connecting portion of the first body portion and the connecting portion of the second body portion have elasticity.

10. The socket contact of claim 1, wherein the connecting portion of the first body portion and the connecting portion of the second body portion are in different planes.

11. The socket contact of claim 10, wherein the different planes are parallel with each other.

12. The socket contact of claim 10, wherein, when the socket contact is positioned in a housing for testing a semiconductor, the connecting portion of the second body portion overlaps and is in a different plane from a connecting portion of a first body portion of an adjacent socket contact positioned in the housing.

13. The socket contact of claim 1, wherein, when the socket contact is positioned in a housing for testing a semiconductor, the connecting portion of the second body portion overlaps the connecting portion of the first body portion of an adjacent socket contact positioned in the housing.

14. The socket contact of claim 1, further comprising a fixing portion protruding from the first contact portion or the second contact portion for fixing the socket contact in a housing for testing a semiconductor.

15. The socket contact of claim 1, wherein, when the socket contact is positioned in a housing for testing a semiconductor, the first contact portion is electrically connected to an integrated circuit and the second contact portion is electrically connected to a circuit board.

16. A socket contact comprising:
a first contact portion positioned at a first end of the socket contact;
a second contact portion positioned at a second end of the socket contact; and
a first connecting portion and a second connecting portion connected between the first and second contact portions, wherein the first connecting portion is in a different plane from the second connecting portion, and the first and second connecting portions protrude in different directions with respect to an imaginary line connecting the first and second contact portions.

17. The socket contact of claim 16, wherein the first and second connecting portions each comprise at least two legs making an oblique angle with respect to each other, and with respect to the imaginary line connecting the first and second contact portions.

18. The socket contact of claim 16, wherein the plane of the first connecting portion is parallel to the plane of the second connecting portion.

19. The socket contact of claim 16, wherein, when the socket contact is positioned in a housing for testing a semiconductor, the second connecting portion overlaps and is in a different plane from a first connecting portion of an adjacent socket contact positioned in the housing.

20. The socket contact of claim 16, further comprising a fixing portion protruding from the first contact portion or the second contact portion for fixing the socket contact in a housing for testing a semiconductor.
